(19) United States
(12) Patent Application Publication
(10) Pub. No.: US 2012/0103413 A1
(43) Pub. Date: May 3, 2012

(54) THIN-FILM SOLAR CELL AND METHOD FOR FABRICATING THE SAME

(75) Inventors: Chin-Yao Tsai, Tainan (TW); Chih-Wei Chang, Tainan (TW); Ching-In Wu, Tainan (TW); Kai-Hsiang Chuang, Tainan (TW); Chih-Hsiung Chang, Tainan (TW); Kun-Chih Lin, Tainan (TW)

(73) Assignee: AURIA SOLAR CO., LTD., Tainan (TW)

(21) Appl. No.: 13/347,969

(22) Filed: Jan. 11, 2012

(30) Foreign Application Priority Data
Jul. 29, 2011 (TW) 100127116

(51) Int. Cl. H01L 31/02; H01L 31/18

(52) U.S. Cl. 136/256; 438/64; 257/E31.117

(57) ABSTRACT

A thin-film solar cell includes a body and a polymer layer. The body includes a first electrode layer, a photoelectric conversion layer, and a second electrode layer, and the polymer layer includes a hardening material and an interface material. The photoelectric conversion layer is disposed between the first electrode layer and the second electrode layer, and the polymer layer surrounds the photoelectric conversion layer, in which the interface material is used for bonding to the hardening material and the photoelectric conversion layer respectively. Therefore, the thin-film solar cell may reduce the Staebler-Wronski Effect generated by the photoelectric conversion layer in the photoelectric conversion procedure. Accordingly, the photoelectric conversion efficiency is improved.

### CROSS-REFERENCE TO RELATED APPLICATIONS

This non-provisional application claims priority under 35 U.S.C. §119(a) on Patent Application No(s). 100127116 filed in Taiwan, R.O.C. on Jul. 29, 2011, the entire contents of which are hereby incorporated by reference.

### BACKGROUND

1. Technical Field

The disclosure relates to a thin-film solar cell and a method for fabricating the same, and more particularly to a thin-film solar cell having an amorphous silicon photoelectric conversion layer and a method for fabricating the same.

2. Related Art

Recently, with the rise of the public awareness of environmental protection, people attach importance to research and development of renewable energies. Compared with other renewable energies, the solar ray can be easily obtained, so people in the industry invest a great amount of capital in developing solar power generation.

Recently, solar cells may be classified into two types in which the first type of the solar cell is referred to as bulk-like solar cell, and the second type of the solar cell is referred to as thin-film type solar cell (hereafter referred to as thin-film solar cell). The biggest differences between the bulk-like solar cell and the thin-film solar cell lie in the thicknesses of the photoelectric conversion layers and the main materials of the photoelectric conversion layers. The thickness of the photoelectric conversion layer of the bulk-like solar cell is larger when comparing with that of the bulk-like solar cell. Besides, the main materials of the photoelectric conversion layer of the bulk-like solar cell are monocrystalline silicon and polycrystalline silicon, but the thin-film solar cell are made of amorphous silicon and a compound (for example, gallium arsenide or indium phosphide). Although the photoelectric conversion efficiency of the bulk-like solar cell is higher than that of the thin-film solar cell, as electronic products are developed towards getting light, thin, short, and small, the volume of the bulk-like solar cell is still larger than that of the thin-film solar cell, so the bulk-like solar cell is not popular and widespread. Further, the fabricating cost of the thin-film solar cell is lower than that of the bulk-like solar cell (the fabricating cost of amorphous silicon is lower than that of monocrystalline silicon or polycrystalline silicon), so that people attach importance to the development of the thin-film solar cell.

In addition, in order to maximize the output power of the thin-film solar cell, the characteristics of semiconductor materials absorbing lights of different wavelengths in the sunlight may be utilized by stacking up semiconductor materials in a tandem manner. FIG. 1 is a schematic cross-sectional structural view of a conventional tandem type thin-film solar cell. Referring to FIG. 1, the thin-film solar cell 100 comprises a first electrode layer 102, a first photoelectric conversion layer 104, a second photoelectric conversion layer 106, and a second electrode layer 108. The second photoelectric conversion layer 106 was disposed on the first photoelectric conversion layer 104. Also, the first photoelectric conversion layer 104 and the second photoelectric conversion layer 106 can absorb the different lights of different wavelengths (that is, the first photoelectric conversion layer 104 is connected to the second photoelectric conversion layer 106 in series).

In the thin-film solar cell 100, through the property that the first photoelectric conversion layer 104 and the second photoelectric conversion layer 106 absorb the different lights of different wavelengths and the serial connection characteristic that the first photoelectric conversion layer 104 is connected to the second photoelectric conversion layer 106 in series (that is, the tandem type thin-film solar cell), the output power of the thin-film solar cell 100 is higher than that of a thin-film solar cell which has the same area for receiving light as the thin-film solar cell 100 and only one single photoelectric conversion layer. In this embodiment, the first photoelectric conversion layer 104 may be made of amorphous silicon, and can absorb the short-wavelength light (the light having a wavelength in a range of approximately 400 to 700 nanometers (nm)); the second photoelectric conversion layer 106 may be made of microcrystalline silicon, and can absorb the long-wavelength light (the light having a wavelength in a range of approximately 700 to 1100 nm), and the output voltage of the thin-film solar cell 100 is approximately 1.3 volts (V).

It should be noted that, although the amorphous silicon photoelectric conversion layer has the advantage of low fabricating cost, the Staebler-Wronski Effect may be generated during the photoelectric conversion, so the photoelectric conversion efficiency of the thin-film solar cell 100 is lowered. Therefore, how to reduce the Staebler-Wronski Effect generated by the photoelectric conversion layer during the photoelectric conversion becomes an important topic for people in the industry in the development of the thin-film solar cell.

### SUMMARY

In order to respond to the demand of the development of thin-film solar cells, the disclosure relates to a thin-film solar cell, so as to solve the problem, that the photoelectric conversion efficiency is lowered due to the Staebler-Wronski Effect of a photoelectric conversion layer during the photoelectric conversion.

According to an embodiment of the present invention, a thin-film solar cell comprises a body and a polymer layer. The body comprises a first electrode layer, an amorphous silicon photoelectric conversion layer, and a second electrode layer. The polymer layer comprises a hardening material and an interface material. The amorphous silicon photoelectric conversion layer is disposed between the first electrode layer and the second electrode layer. The polymer layer surrounds the photoelectric conversion layer, and the interface material is used for bonding the hardening material to the photoelectric conversion layer.

In an embodiment, the hardening material is aliphatic amines.

In an embodiment, the hardening material comprises methylamine, dimethylamine, trimethylamine, ethylamine, diethylamine, and triethylamine.

In an embodiment, the interface material is amino silanes.

In the thin-film solar cell according to an embodiment of the disclosure, molecular weights of the hardening material and the interface material are higher than that of the photoelectric conversion layer, so that the heat, i.e. phonons, generated by the photoelectric conversion layer due to the Staebler-Wronski Effect is not transferred easily through the hardening material and the interface material, thereby the photoelectric conversion efficiency is improved. Further, through the thermal energy generated during a hardening reaction between the interface material and the hardening material, the photoelectric conversion layer is annealed, and, therefore, the photoelectric conversion efficiency is improved, either.

An embodiment discloses a method for fabricating a thin-film solar cell, which comprises: forming an amorphous-silicon photoelectric conversion layer on a first electrode layer; forming a second electrode layer on the amorphous silicon photoelectric conversion layer, and forming a polymer layer surrounding the photoelectric conversion layer. The polymer layer comprises a hardening material and an interface material, and the interface material is used for bonding the hardening material to the photoelectric conversion layer.

In an embodiment, the step of forming the polymer layer surrounding the photoelectric conversion layer comprises performing a screen printing, coating, or spraying process for making the photoelectric conversion layer be surrounded with the hardening material and the interface material.

In an embodiment, the step of forming the amorphous-silicon photoelectric conversion layer on the first electrode layer comprises depositing the amorphous-silicon photoelectric conversion layer on the first electrode layer through Radio Frequency Plasma Enhanced Chemical Vapor Deposition (RF PECVD), Very High Frequency Plasma Enhanced Chemical Vapor Deposition (VHF PECVD), or Microwave Plasma Enhanced Chemical Vapor Deposition (MW PECVD).

In the method for fabricating the thin-film solar cell of the present invention, through the screen printing, coating, or spraying process, the photoelectric conversion layer is surrounded by the hardening material and the interface material, so that the Staebler-Wronski Effect generated by the photoelectric conversion layer is reduced.

### BRIEF DESCRIPTION OF THE DRAWINGS

The present invention will become more fully understood from the detailed description given herein below for illustration only, and thus are not limitative of the present invention, and wherein:

FIG. 1 is a schematic cross-sectional structural view of an embodiment of a conventional tandem type thin-film solar cell;

FIG. 2 is a schematic cross-sectional structural view of an embodiment of a thin-film solar cell of the present invention;

FIG. 3 is a schematic view of a process for fabricating the thin-film solar cell in FIG. 2;

FIG. 4 is a diagram illustrating a relation between the conversion efficiency and the number of days in three cycle experiments of the thin-film solar cells having microcrystalline silicon photoelectric conversion layers of different thicknesses in FIG. 1 and FIG. 2;

FIG. 5 is a diagram illustrating a relation between the conversion efficiency and the number of days of a Building-Integrated Photovoltaic in an application of the thin-film solar cells in FIG. 1 and FIG. 2; and

FIG. 6 is a schematic cross-sectional structural view of another embodiment of a thin-film solar cell of the present invention.

### DETAILED DESCRIPTION OF THE INVENTION

In the description of embodiments in the following, a tandem type thin-film solar cell is taken as an example, but the present invention is not limited thereto.

FIG. 2 is a schematic cross-sectional structural view of an embodiment of a thin-film solar cell of the present invention. Referring to FIG. 2, the thin-film solar cell 200 comprises a body 202 and a polymer layer 204. The body 202 comprises a first electrode layer 206, a photoelectric conversion layer 207 and a second electrode layer 212. In this embodiment, the photoelectric conversion layer 207 may be an amorphous-silicon photoelectric conversion layer 208, a microcrystalline silicon photoelectric conversion layer 210, but is not limit to the above-mentioned silicon materials. For instance, the photoelectric conversion layer material 207 is amorphous silicon, microcrystalline silicon, a combination of amorphous silicon and monocrystalline silicon, a combination of microcrystalline silicon and monocrystalline silicon, a combination of amorphous silicon and polycrystalline silicon, a combination of microcrystalline silicon and polycrystalline silicon, a combination of amorphous silicon and microcrystalline silicon, a combination of amorphous silicon, microcrystalline silicon and polycrystalline silicon or a combination of amorphous silicon, microcrystalline silicon, monocrystalline silicon and polycrystalline silicon.

The material of the first electrode layer 206 may be Transparent Conducting Oxides (TCO), but is not limited to the above-mentioned material. The material of the TCO may be, but is not limited to, Indium Tin Oxide (ITO), Indium Sesquioxide (In₂O₃), Tin Dioxide (SnO₂), Zinc Oxide (ZnO), Cadmium Oxide (CdO), Al doped Zinc Oxide (AZO), or Indium Zinc Oxide (IZO). The material of the second electrode layer 212 may be TCO or metal (for example, silver or aluminum), but is not limited to the above-mentioned materials.

The amorphous silicon photoelectric conversion layer 208 may comprise a P-type amorphous silicon thin film, an intrinsic amorphous silicon thin film, and an N-type amorphous silicon thin film, and the microcrystalline silicon photoelectric conversion layer 210 may comprise a P-type microcrystalline silicon thin film, an intrinsic microcrystalline silicon thin film, and an N-type microcrystalline silicon thin film. The polymer layer 204 comprises a hardening material and an interface material. The hardening material may be aliphatic amines, but is not limited to the above-mentioned material and the interface material may be amino silanes, but is not limited to the above-mentioned material. In this embodiment, the hardening material may comprise methylamine, dimethylamine, trimethylamine, ethylamine, diethylamine, and triethylamine, and the interface material may be [3-(2-aminoethylamine) propyltrimethoxysilane. This embodiment is not intended to limit the present invention, and the detailed description of the polymer layer 204 is described hereafter.

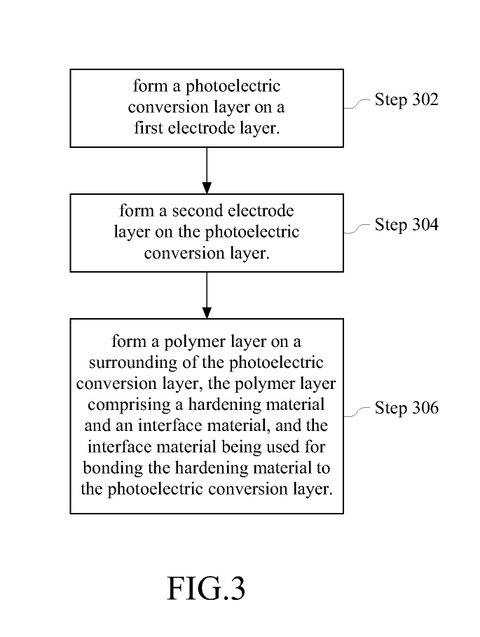

FIG. 3 is a schematic view of a process for fabricating a thin-film solar cell in FIG. 2. Referring to FIG. 3, a method for fabricating the thin-film solar cell 200 comprises the following steps.

In Step 302, a photoelectric conversion layer is formed on a first electrode layer.

In Step 304, a second electrode layer is formed on the photoelectric conversion layer.

In Step 306, a polymer layer is formed on a surrounding of the photoelectric conversion layer. An interface material is used for bonding the hardening material to the photoelectric conversion layer.

In Step 302, the photoelectric conversion layer 207 may include the amorphous silicon photoelectric conversion layer 208 and the microcrystalline silicon photoelectric conversion layer 210. The amorphous silicon photoelectric conversion layer 208 and the microcrystalline silicon photoelectric conversion layer 210 may be respectively formed on the first electrode layer 206 and the amorphous silicon photoelectric conversion layer 208 through Chemical Vapor Deposition (CVD), but not limited to the above-mentioned method. The CVD may be RF PECVD, VHF PECVD, or MW PECVD, but not limited to the above-mentioned methods.

In Step 304, the method for forming the second electrode layer 212 on the photoelectric conversion layer 207 (that is, the second electrode layer 212 on the microcrystalline silicon photoelectric conversion layer 210) may be electron beam evaporation, Physical Vapor Deposition (PVD), or sputtering deposition, but not limited to the above-mentioned methods. The method is determined according to the properties (for example, but not limited to, the boiling point) of the material of the actual second electrode layer 212.

In Step 306, the method for forming the polymer layer 204 on the surrounding of the photoelectric conversion layer 207 (that is, the amorphous silicon photoelectric conversion layer 208 and the microcrystalline silicon photoelectric conversion layer 210) may be screen printing, coating, or spraying so as to make the hardening material and the interface material surround the photoelectric conversion layer 207 (that is, the amorphous silicon photoelectric conversion layer 208 and the microcrystalline silicon photoelectric conversion layer 210), but not limited to the above-mentioned methods. In other words, the method of surrounding the photoelectric conversion layer 207 with the polymer layer 204 may be adjusted according to the properties of the material of the hardening material and the interface material, for example, the boiling point, but not limited to the above-mentioned property. The surrounding above mentioned is a portion of the surface of the photoelectric conversion layer 207 (that is, the amorphous silicon photoelectric conversion layer 208 and the microcrystalline silicon photoelectric conversion layer 210) which is exposed to the external environment.

In this embodiment, the polymer layer 204 is used for covering the amorphous silicon photoelectric conversion layer 208, the microcrystalline silicon photoelectric conversion layer 210, and the second electrode layer 212 (that is, the polymer layer 214 may prevent the amorphous silicon photoelectric conversion layer 208, the microcrystalline silicon photoelectric conversion layer 210, and the second electrode layer 212 from contacting with the external environment). Moreover, FIG. 2 is the schematic cross-sectional structural view of the thin-film solar cell 200, as shown in FIG. 2 that the polymer layer 204 only covers first side 40 and first side 41 of the amorphous silicon photoelectric conversion layer 208, second side 42 and second side 43 of the microcrystalline silicon photoelectric conversion layer 210, and third side 44 and third side 45 and top side 46 of the second electrode layer 212.

In addition, in Step 308, the interface material (that is, 3-(2-aminoethylamino)propyltrimethoxysilane) may be used for bonding the hardening material (that is, a mixture comprising methylamine, dimethylamine, trimethylamine, ethylamine, diethylamine and triethylamine) to the amorphous silicon photoelectric conversion layer 208 and bonding the hardening material to the microcrystalline silicon photoelectric conversion layer 210. More specifically, siloxane (Si(OCH₃)) in the interface material (that is, 3-(2-aminoethylamino)propyltrimethoxysilane) may bond to the amorphous silicon molecules in the amorphous silicon photoelectric conversion layer 208 and microcrystalline silicon molecules the microcrystalline silicon photoelectric conversion layer 210; the 3-(2-aminoethylamino)propyl radicals (that is, H₂NCH₂CH₂NH(CH₂)₃⁻) in the interface material (that is, 3-(2-aminoethylamino)propyltrimethoxysilane) may bond to the amino radicals (that is, NH₃, NH₂⁻, and NH²⁻) in the hardening material (that is, the mixture comprising methylamine, dimethylamine, trimethylamine, ethylamine, diethylamine and triethylamine), so that the polymer layer 204 covers and protects the amorphous silicon photoelectric conversion layer 208, the microcrystalline silicon photoelectric conversion layer 210, and the second electrode layer 212. While the interface material and the hardening material undergo a hardening reaction, thermal energy is generated from the hardening reaction, and the thermal energy generated is used for annealing.

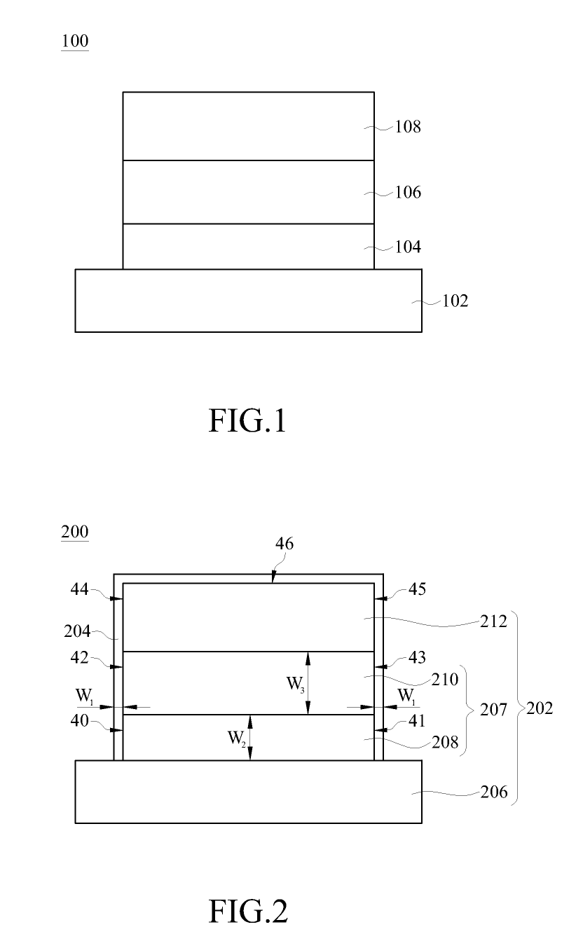

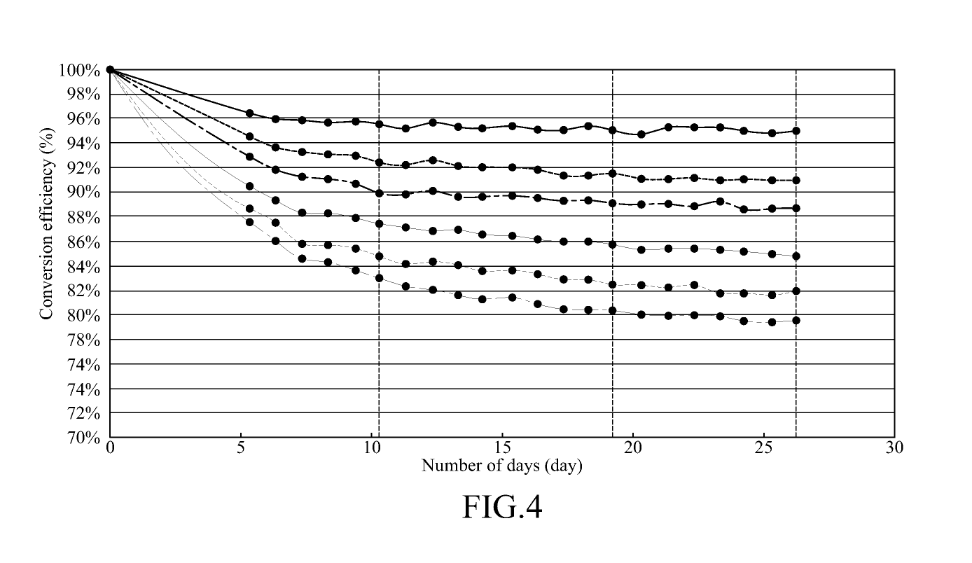

Next, an experiment is performed in which the thin-film solar cells having the microcrystalline silicon photoelectric conversion layers of different thicknesses in FIG. 1 and FIG. 2 undergoes three cycles. In each cycle, the thin-film solar cell accumulatively receives radiant energy of 43,000 watts per hour per square meter. In this experiment, the first cycle is from the 1^{st} day to the 10^{th} day, the second cycle is from the 11^{th} day to the 19^{th} day, and the third cycle is from the 20^{th} day to the 26^{th} day. In addition, from the 5^{th} day, the output power of the thin-film solar cells having the microcrystalline silicon photoelectric conversion layers of different thicknesses of FIG. 1 and FIG. 2 are measured each day. For the experiment results, reference is made to Table 1 and FIG. 4. FIG. 4 is a diagram illustrating a relation between the conversion efficiency and the number of days in the three-cycle experiment of the thin-film solar cells having the microcrystalline silicon photoelectric conversion layers of the different thicknesses in FIG. 1 and FIG. 2. Also, the conversion efficiency is defined through Equation 1 below:

Cd=P_{stb}/Pᵢₙᵢ (Equation 1)

where Cd is the conversion efficiency, Pᵢₙᵢ is an initial output power (that is, an output power when the experiment just started), and P_{stb} is an output power in steady state. The steady state is the state that after the thin-film solar cells undergoing three cycles, the differences between the highest and lowest output powers divided by the average output power is smaller than 2 percent. The thick line in FIG. 4 is the experiment result of the thin-film solar cell of FIG. 2, the thin line is the experiment result of the thin-film solar cell of FIG. 1, the solid line is the experiment result of the microcrystalline silicon photoelectric conversion layer having the thickness of 800 nm, the dashed line is the experiment result of the microcrystalline silicon photoelectric conversion layer having the thickness of 1000 nm, and the center line, having alternate long and short dashes, is the experiment result of the microcrystalline silicon photoelectric conversion layer having the thickness of 1200 nm.

TABLE 1

| Thickness of | | | | |
|---|---|---|---|---|
| microcrystalline | | | | |
| silicon | | | | |
| photoelectric | existence of | Pᵢₙᵢ | | |
| conversion layer | polymer | (microwatt, | P_{stb} | Cd |
| (nanometer, nm) | layer | μW) | (microwatt, μW) | (%) |
| 800 | Yes | 119.3 | 113.05 | 94.8 |
| | No | 120.74 | 102.36 | 84.8 |
| 1000 | Yes | 128.95 | 117.27 | 90.9 |
| | No | 128.77 | 105.11 | 81.6 |
| 1200 | Yes | 134.54 | 119.12 | 88.5 |
| | No | 133.09 | 105.62 | 79.4 |

It can be observed from Table 1 and FIG. 4 that, the conversion efficiency of the thin-film solar cell 200 having the polymer layer 204 is always higher than that of the thin-film solar cell 100 (that is, the thin-film solar cell without the polymer layer).

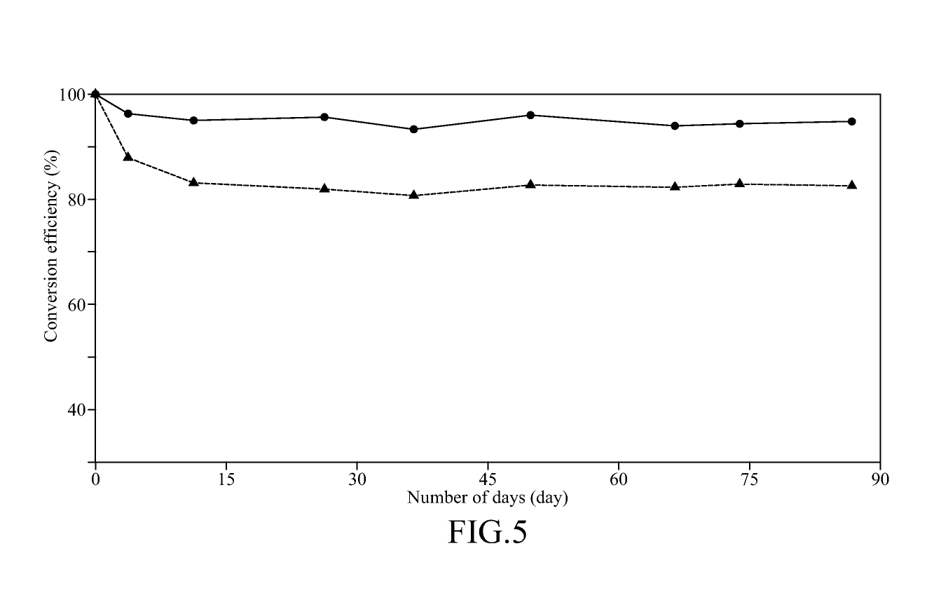

Moreover, FIG. 5 is a diagram illustrating a relation between the conversion efficiency and the number of days of a Building-Integrated Photovoltaic in an application of the thin-film solar cells in FIG. 1 and FIG. 2. As shown in FIG. 5, the thick line in FIG. 5 is the experiment result of a Building-Integrated Photovoltaic in an application of the thin-film solar cell of FIG. 2, the thin line in FIG. 5 is the experiment result of a Building-Integrated Photovoltaic in an application the thin-film solar cell of FIG. 1. It can be observed from FIG. 5 that, the conversion efficiency of the Building-Integrated Photovoltaic in an application the thin-film solar cell 200 having the polymer layer 204 is always higher than that of the Building-Integrated Photovoltaic in an application the thin-film solar cell 100 (that is, the thin-film solar cell without the polymer layer)

Accordingly, the thin-film solar cell 200 having the polymer layer 204 can effectively reduce the Staebler-Wronski Effect generated by the photoelectric conversion layer 207 (that is, the amorphous silicon photoelectric conversion layer 208 and the microcrystalline silicon photoelectric conversion layer 210) during the photoelectric conversion, and, therefore, improves the photoelectric conversion efficiency.

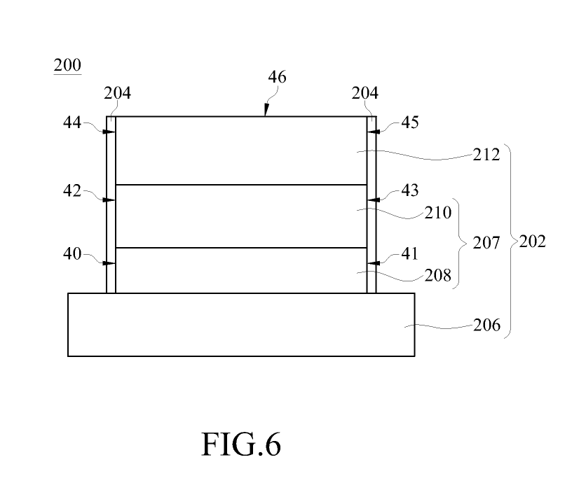

The polymer layer 204 in the above embodiment may cover the amorphous silicon photoelectric conversion layer 208, the microcrystalline silicon photoelectric conversion layer 210, and the second electrode layer 212 (that is, the polymer layer 204 prevents the amorphous silicon photoelectric conversion layer 208, the microcrystalline silicon photoelectric conversion layer 210, and the second electrode layer 212 from contacting with the external environment), but this embodiment is not intended to limit the present invention. In some embodiments, the polymer layer 204 may only cover the side surfaces of the amorphous silicon photoelectric conversion layer 208, the microcrystalline silicon photoelectric conversion layer 210, and the second electrode layer 212 and leave the top surface 46 of the amorphous silicon photoelectric conversion layer 208 exposed to the external circumstance (referring to FIG. 6, which is a schematic cross-sectional structural view of another embodiment of a thin-film solar cell of the present invention). FIG. 6 is the schematic cross-sectional structural view of the thin-film solar cell 200, so it is shown in FIG. 6 that the polymer layer 204 only covers first side 40 and first side 41 of the amorphous silicon photoelectric conversion layer 208, second side 42 and second side 43 of the microcrystalline silicon photoelectric conversion layer 210, and third side 44 and third side 45 of the second electrode layer 212.

In the method for fabricating the thin-film solar cell of the present invention, through screen printing, coating, or spraying, the hardening material and the interface material cover the photoelectric conversion layer (that is, prevent the photoelectric conversion layer from contacting with the external environment), so as to fabricate the thin-film solar cell having the polymer layer (that is, the thin-film solar cell of the disclosure of the present invention). In the thin-film solar cell of the disclosure, as molecular weights of the hardening material and the interface material are higher than that of the silicon material, it is not easy for the hardening material and the interface material to transfer the thermal energy (that is, phonons) generated by the photoelectric conversion layer due to the Staebler-Wronski Effect. Further, through the thermal energy generated during the interface material bonding the hardening material to the photoelectric conversion layer, the photoelectric conversion layer is annealed so as to improve the photoelectric conversion efficiency of the thin-film solar cells.

What is claimed is:

1. A thin-film solar cell, comprising:
a body, comprising a first electrode layer, a second electrode layer, and a photoelectric conversion layer disposed between the first electrode layer and the second electrode layer; and
a polymer layer, covering the photoelectric conversion layer, and comprising a hardening material and an interface material, the interface material being used for bonding the hardening material to the photoelectric conversion layer.

2. The thin-film solar cell according to claim 1, wherein the hardening material is aliphatic amines.

3. The thin-film solar cell according to claim 1, wherein the hardening material comprises methylamine, dimethylamine, trimethylamine, ethylamine, diethylamine, and triethylamine.

4. The thin-film solar cell according to claim 1, wherein the interface material is amino silanes.

5. The thin-film solar cell according to claim 1, wherein the photoelectric conversion layer material is amorphous silicon, microcrystalline silicon, a combination of amorphous silicon and monocrystalline silicon, a combination of microcrystalline silicon and monocrystalline silicon, a combination of amorphous silicon and polycrystalline silicon, a combination of microcrystalline silicon and polycrystalline silicon, a combination of amorphous silicon and microcrystalline silicon, a combination of amorphous silicon, microcrystalline silicon and polycrystalline silicon or a combination of amorphous silicon, microcrystalline silicon, monocrystalline silicon and polycrystalline silicon.

6. A method for fabricating a thin-film solar cell, comprising:
forming a photoelectric conversion layer on a first electrode layer;
forming a second electrode layer on the photoelectric conversion layer; and
forming a polymer layer on a surrounding of the photoelectric conversion layer, the polymer layer comprising a hardening material and an interface material, and the interface material being used for bonding the hardening material to the photoelectric conversion layer.

7. The method for fabricating the thin-film solar cell according to claim 6, wherein the step of forming the polymer layer on the at least one side surface of the photoelectric conversion layer comprises covering the at least one side surface of the photoelectric conversion layer with the hardening material and the interface material by screen printing, coating, or spraying process.

8. The method for fabricating the thin-film solar cell according to claim 6, wherein the step of forming the photoelectric conversion layer on the first electrode layer comprises depositing the photoelectric conversion layer on the first electrode layer through radio frequency plasma enhanced chemical vapor deposition (RF PECVD), very high frequency plasma enhanced chemical vapor deposition (HF PECVD), or microwave plasma enhanced chemical vapor deposition (MW PECVD).
